(19) United States
(12) Patent Application Publication
(10) Pub. No.: US 2012/0087508 A1
(43) Pub. Date: Apr. 12, 2012

(54) COMPUTER ENABLED KARAOKE MACHINE

(75) Inventor: Brian R. Shim, Providence, RI (US)

(73) Assignee: ION AUDIO, LLC, Cumberland, RI (US)

(21) Appl. No.: 13/215,600

(22) Filed: Aug. 23, 2011

Related U.S. Application Data
(60) Provisional application No. 61/390,640, filed on Oct. 7, 2010.

(51) Int. Cl. H03G 3/00; H04B 1/00

(52) U.S. Cl. 381/63; 381/119; 381/61; 381/104

(57) ABSTRACT

A karaoke machine with an integrated computer interface device is disclosed. The karaoke machine includes at least one microphone input having an audio output. A computer interface device configured and arranged to receive digital audio and convert it to analog audio. At least one speaker is also included. A summing node is provided to combine the analog audio from the computer interface device with the audio output of the microphone input together into combined audio and transmit the combined audio to the speaker.

### CROSS-REFERENCE TO RELATED APPLICATION

The present patent document claims priority to earlier filed U.S. Provisional Patent Application Ser. No. 61/390,640, filed on Oct. 7, 2011, the entire contents of which are incorporated herein by reference.

### BACKGROUND OF THE INVENTION

1. Field of the Invention

The present patent document relates generally to karaoke machines and more specifically to a karaoke machine that includes a computer interface to enable song selection from the internet.

2. Background of the Related Art

Karaoke is a popular pastime around the world. While there are public venues to do karaoke, many consumers would like to be able to have karaoke parties at home, or just prefer the privacy of a home environment to practice singing.

The most popular solution for the home karaoke customer has been the use of a karaoke machine. A karaoke machine generally includes a CD+G player with integrated amplifier, and one or more speakers and microphones. These prior art karaoke machines use CD+G media, which is a compact disc format that includes lyric information encoded onto it. CD+G media typically cost in the range from $9.99 to $15.99 each, new, and may contain 6 to 12 songs.

There are several problems with this system however. First, the consumer is forced to purchase an entire disc of songs even if he or she only wants one of the songs on the disc. Second, if the consumer is having a party, he or she is limited to the songs that he or she has already purchased. If someone requests a song that he or she did not previously purchase, they, understandably, will not be able to do karaoke for that song. Because singers expect to have thousands of songs to choose from, this situation makes home karaoke parties impractical without renting professional karaoke equipment, which come bundled with a large catalog of CD+G media.

Therefore, although prior art karaoke machines are fine for practicing using the

CD+G media the consumer has purchased, they are not suited for a home karaoke party unless the consumer desires to spend a lot of money purchasing thousands of songs on CD+G media.

The Internet, however, provides a partial solution. Now, using computer software, it is possible to purchase and download individual songs with lyrics encoded in the file from authorized online retailers, and play them on a home computer. The disadvantage, though, is that the computer is not an ideal audio device for performing karaoke. Most laptops have tiny speakers. Tower computers might have slightly better desktop speakers, but these are still not suited for high volume playback. Also, computers only have one microphone input, while most karaoke machines have two microphone inputs, which are needed to perform songs requiring multiple singers, such as duets.

Accordingly, there is a perceived need in the industry for a karaoke machine that permits a user to have access to a large karaoke library with the needed expense thereof

### SUMMARY OF THE INVENTION

This invention combines the best features of the home karaoke machine with the song selection available on the Internet. A consumer no longer is required to purchase CD+G discs to get songs. The invention combines karaoke software running on a computer connected to the Internet with a low-cost integrated karaoke audio system connected to the computer.

### BRIEF DESCRIPTION OF THE DRAWINGS

These and other features, aspects, and advantages of the present invention will become better understood with reference to the following description, appended claims, and accompanying drawings where:

FIG. 1 is a front perspective view of an embodiment of the internet enabled karaoke machine of the present invention;

FIG. 2 is a rear view of an embodiment of the internet enabled karaoke machine of the present invention

FIG. 3 is a schematic diagram of the operation of an embodiment the internet enabled karaoke machine of the present invention.

### DESCRIPTION OF THE PREFERRED EMBODIMENT

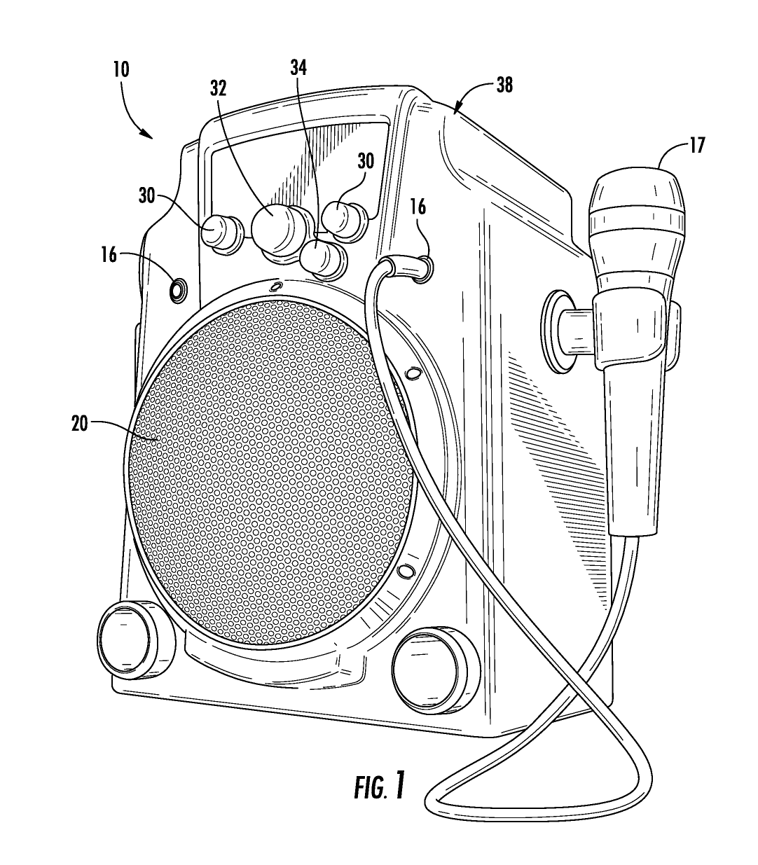

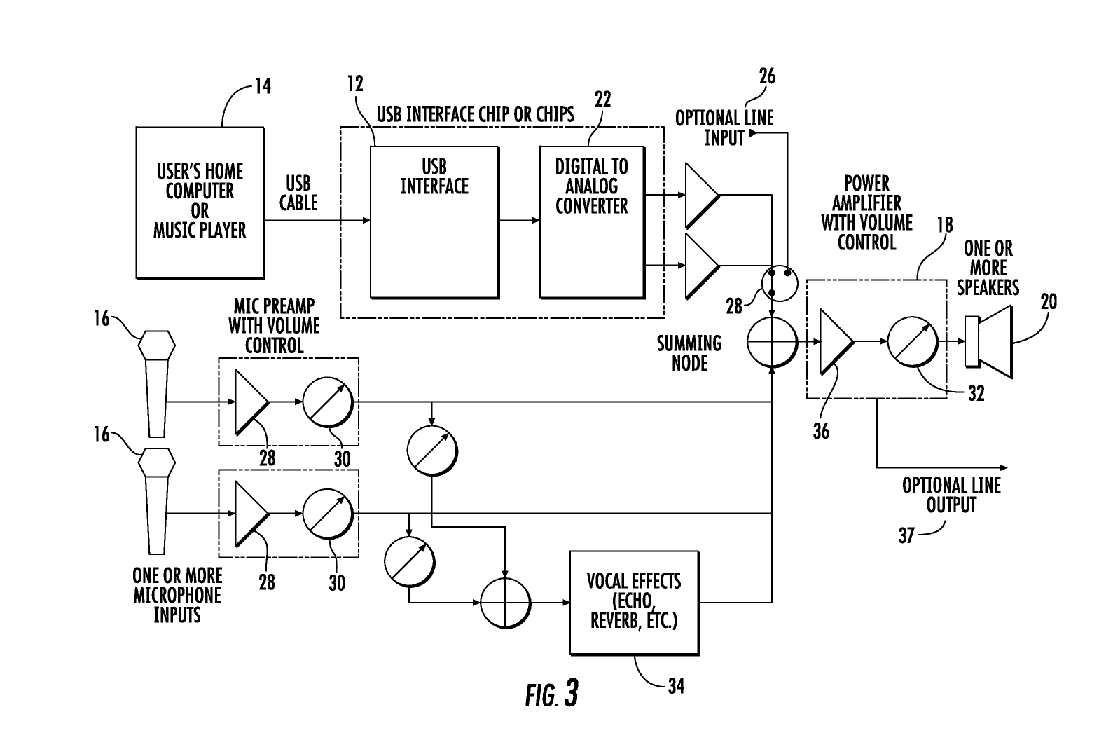

Referring now to FIGS. 1-3, the karaoke machine and system of the present invention is shown generally at 10. A karaoke machine of the present invention includes a computer interface device 12 for streaming audio from a computer 14 and at least one microphone input 16. The input 16 from the microphone(s) 17 and computer interface device 12 are mixed together, amplified through an onboard amplifier 18, and played through one or more onboard speakers 20.

Specifically, the karaoke machine 10 of the present invention includes a computer interface device 12 configured to stream audio from a computer 14 (or portable music player, such as an mp3 player or tablet computer) to the karaoke machine 10. In one embodiment, a universal serial bus (“USB”) interface may be used. An analog to digital converter 22 is connected to the computer interface device 12 to convert the digital audio signals streaming from the personal computer 14 to analog audio. The analog audio is then combined with audio from one or more microphones 17 described further below. Preferably, the port 24 of the computer interface device 12 may be located on the rear of the karaoke machine 10. However, the port 24 may be located on any surface of the karaoke machine 10.

In addition, the karaoke machine 10 includes a switchable line input 26 that can be toggled in lieu of audio from the computer interface device 12. The switch 28 toggles between the analog audio from the computer interface device 12 recevied through port 24 and audio from the line input 26. The line input 26 is useful for obtaining audio from computing devices that do not include a USB port, but have an audio line output, such as a headphone jack. For example, audio from a tablet computer (or a music player with a display) may be routed from the headphone jack to the karaoke machine through the line input 26 while lyrics are displayed on the tablet computer's (or music player's) display.

The karaoke machine 10 of the present invention also includes one or more microphone inputs 16. Input from the microphone inputs 16 is passed through a preamplifier 28, which may have an optional volume control 30. In a preferred embodiment, two ¼″ microphone inputs 16 are provided on the front of the karaoke machine 10 of the present invention, each with a volume control 30. Input from the microphone inputs 16 may also have selectable vocal effects, such as “echo” or “reverb”. The smaller knob to the lower right of the master volume control 32 is the effect level control 34. In the embodiment shown in FIG. 1, a single effect level control 32 is provided to affect both microphones 17. However, individual controls for each microphone 17 may also be provided as well.

After the input from the microphone inputs 16 has passed through the preamplifiers and had any vocal effects applied thereto, the input is combined with the analog audio from the digital to analog converter 22 (or from the line input 26 if switch 28 is toggled) into a combined audio signal.

The combined audio signal is passed through an amplifier 36 with a master volume control 32 and played through one or more speakers 20. In the preferred embodiment, the karaoke machine 10 includes a master volume control 32 (depicted as the large knob in the middle of the karaoke machine 10 shown in FIG. 1). Optionally, the combined audio output may be routed through a line output 37, which may be configured as a pair of RCA jacks other connectors as is known in the art, to permit eh karaoke machine to be connected to an external speakers and/or amplifiers.

Other embodiments of the invention may have a different number of microphone inputs 16 or a different number of speakers 20.

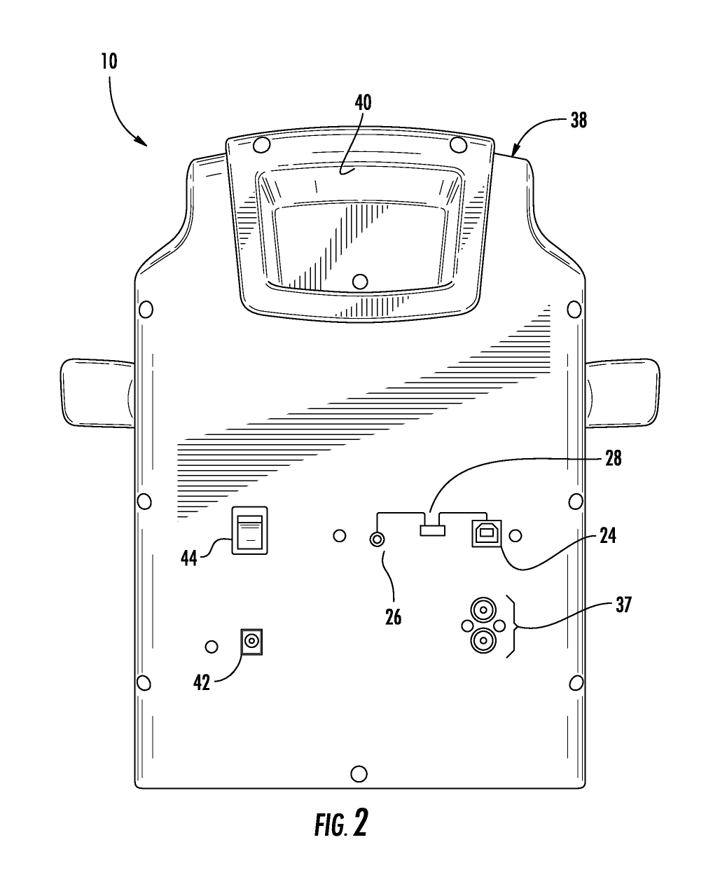

As shown in FIGS. 1 and 2, the karaoke machine 10 of the present invention is preferably enclosed in a compact housing 38 that includes an integrated handle 40 to easily carry the karaoke machine 10. The rear of the karaoke machine 10 also includes a DC power input 42 and power switch 44.

Therefore, it can be seen that the present invention provides a unique solution to the problem of providing an inexpensive solution to the problem of providing a home karaoke machine that has access to a large catalog of CD+G media through a personal computer, without the cost of purchasing many CD+G discs. The user can browse large catalog songs with encoded lyrics from an authorized online retailer and purchase only those songs desired without purchasing an entire CD+G media with unwanted songs. The user can then immediately perform karaoke with those just purchased songs through the karaoke machine of the present invention instead of using the limited and unsuitable audio functionality of most home personal computers.

It would be appreciated by those skilled in the art that various changes and modifications can be made to the illustrated embodiments without departing from the spirit of the present invention. All such modifications and changes are intended to be within the scope of the present invention.

What is claimed is:

1. A karaoke machine, comprising:
at least one microphone input having an audio output;
a computer interface device configured and arranged to receive digital audio and convert it to analog audio;
at least one speaker; and
a summing node configured and arranged to combine the analog audio from the computer interface device with the audio output of the at least one microphone input together into a combined audio signal and transmit the combined audio signal to the at least one speaker.

2. The karaoke machine of claim 1, further comprising a line input having analog audio that is switchable in place of the analog audio of the computer interface device.

3. The karaoke machine of claim 1, further comprising a second microphone input.

4. The karaoke machine of claim 1, wherein the at least one microphone further comprising a effects level control configured to apply a special effect to the audio output of the at least one microphone.

5. The karaoke machine of claim 4, wherein the special effect is selected from the group consisting essentially of reverb and echo.

6. The karaoke machine of claim 1, further comprising a volume control configured to change the volume of audio output of the at least one microphone.

7. The karaoke machine of claim 6, wherein the volume control includes a preamplifier.

8. The karaoke machine of claim 1, further comprising a volume control configured to change the volume of combined audio signal.

9. The karaoke machine of claim 8, further comprising a power amplifier configured to increase the power of the combined audio signal.

10. The karaoke machine of claim 1, further comprising a line output configured to transmit the combined audio signal.

11. The karaoke machine of claim 10, wherein the line output is configured as a pair of RCA jacks.

12. The karaoke machine of claim 1, further comprising a compact housing the having an integrated handle, the compact housing supporting the at least one speaker, the at least one microphone input and the computer interface device.

13. The karaoke machine of claim 1, wherein the computer interface device is a universal serial bus controller.

14. The karaoke machine of claim 13, wherein the universal serial bus controller includes integrated digital-to-analog converters.

15. The karaoke machine of claim 1, wherein the at least one microphone input is a ¼″ microphone jack.
